(19) United States
(12) Patent Application Publication
(10) Pub. No.: US 2017/0358463 A1
(43) Pub. Date: Dec. 14, 2017

(54) ASSEMBLING DEVICE USED FOR SEMICONDUCTOR EQUIPMENT

(71) Applicant: HERMES-EPITEK CORPORATION, Taipei City (TW)

(72) Inventors: Tsan-Hua Huang, Tainan City (TW); Paul Wong, Batu Pahat (MY)

(21) Appl. No.: 15/608,057

(22) Filed: May 30, 2017

(30) Foreign Application Priority Data
Jun. 8, 2016 (TW) 105118226

(51) Int. Cl. H01L 21/67

(52) U.S. Cl. CPC H01L 21/67005

(57) ABSTRACT

The present invention is directed to an assembling device used for semiconductor equipment. The assembling device includes a chamber lid, a ceiling, a suspension part and a driving part. The ceiling is disposed below the chamber lid. The suspension part is inserted through the chamber lid, and to be hooked to the ceiling. The driving part is disposed above the chamber lid and connected to the suspension part, and configured to drive the suspension part to join or separate the ceiling and the chamber lid. The driving part has an elevating unit and a rotating unit. The elevating unit and the rotating unit are respectively configured to elevate and rotate the suspension part.

### BACKGROUND OF THE INVENTION

### 1. Field of the Invention

The present invention generally relates to an assembling device, and more particularly to an automatic assembling device adaptable to semiconductor equipment.

### 2. Description of Related Art

In a film deposition process, a wafer supported on a susceptor in a chamber is exposed to reactant gases that are injected and heated to react or decompose on the wafer to produce a thin film.

A ceiling opposite the susceptor is commonly adopted for guiding flow and controlling temperature. The purpose of guiding flow is to mitigate turbulence and to guide the turbulence out of a growth zone; and the purpose of controlling temperature is to prevent a by-product (e.g., unwanted particles) from adhering to the surface of the ceiling. The by-product on a ceiling with temperature improperly controlled may probably fall onto the wafer. To the contrary, a by-product has less chance of adhering to or falling from the ceiling with temperature properly controlled, thereby enhancing yield of processed wafers.

FIG. 1A and FIG. 1B respectively show a perspective view and a side view of arrangement of a ceiling 110 and a chamber lid 120 for conventional semiconductor equipment 100. The ceiling 110 is manually attached to the chamber lid 120. Specifically, a center fastener 130 of the ceiling 110 is screwed to a center tapped hole of the chamber lid 120. A spacer ring 140 is commonly disposed between the edge of the ceiling 110 and the chamber lid 120 to result in a gap, which needs to be adjusted to control chamber temperature according to composition and flow of reactant gases. Thickness of the spacer ring 140 determines the gap between the ceiling 110 and the chamber lid 120.

However, at least two operators are required to firmly attach the ceiling 10 to the chamber lid 120. Likewise, at least two operators are required to manually unload the ceiling 110 for cleaning. Substantial manpower is thus demanded for loading or unloading the ceiling 110. Further, the ceiling 110 may not be securely attached to the chamber lid 120 as only the center fastener 130 is responsible for supporting the ceiling 110.

A need has thus arisen to propose an automatic assembling device used for semiconductor equipment to increase efficiency and convenience of loading and unloading the ceiling.

### SUMMARY OF THE INVENTION

In view of the foregoing, it is an object of the embodiment of the present invention to provide an automatic assembling device used for semiconductor equipment in order to reduce complexity and labor cost, and to increase use efficiency and convenience effectively.

According to one embodiment, an assembling device used for semiconductor equipment includes a chamber lid, a ceiling, a suspension part and a driving part. The ceiling is disposed below the chamber lid. The suspension part is inserted through the chamber lid and to be hooked to the ceiling. The driving part is disposed above the chamber lid and connected to the suspension part. The driving part is configured to drive the suspension part to join or separate the ceiling and the chamber lid. The driving part includes an elevating unit and a rotating unit. The elevating unit is configured to elevate the suspension part, and the rotating unit is configured to rotate the suspension part.

### BRIEF DESCRIPTION OF THE DRAWINGS

FIG. 1A and FIG. 1B respectively show a perspective view and a side view of arrangement of a ceiling and a chamber lid for conventional semiconductor equipment;

FIG. 2A and FIG. 2B show cross-sectional views of an assembling device adaptable to semiconductor equipment for assembling a ceiling and a chamber lid according to one embodiment of the present invention;

FIG. 2C shows a partial perspective view of the ceiling and the suspension part of the assembling device of FIGS. 2A-2B;

FIG. 2D shows a partial cross-sectional view of the suspension part according to another embodiment of the present invention;

FIG. 2E shows a partial cross-sectional view of the ceiling and the suspension part according to another embodiment of the present invention;

FIG. 2F shows a perspective view of the driving part of the assembling device of FIGS. 2A-2B;

FIG. 3A and FIG. 3B show cross-sectional views of the assembling device adaptable to semiconductor equipment for unloading the ceiling according to another embodiment of the present invention; and

FIG. 3C and FIG. 3D show cross-sectional views of the assembling device adaptable to semiconductor equipment for automatically replacing the ceiling according to another embodiment of the present invention.

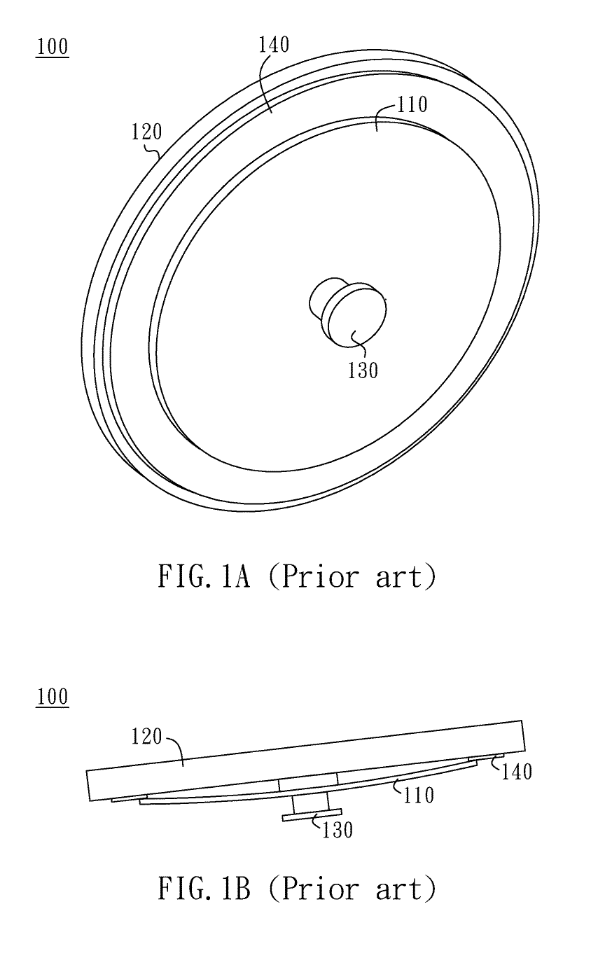

### DETAILED DESCRIPTION OF THE INVENTION

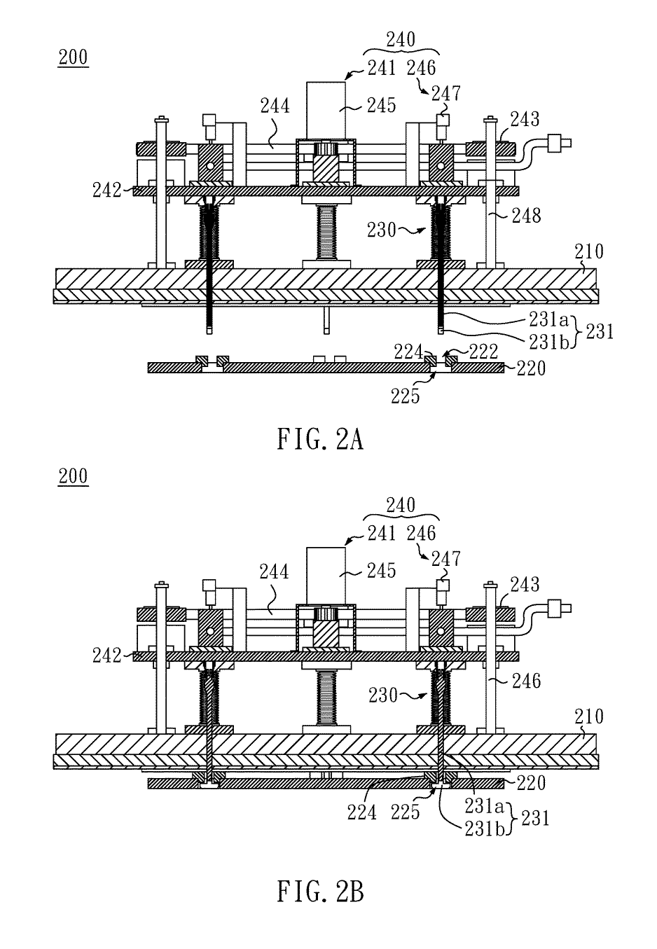

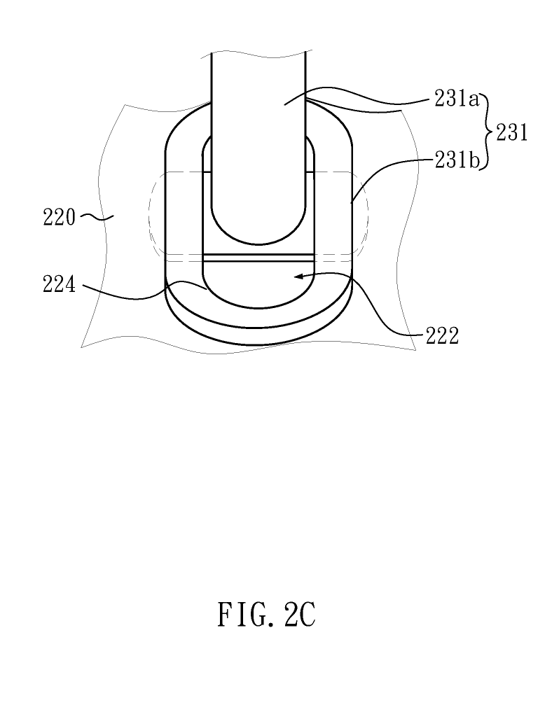

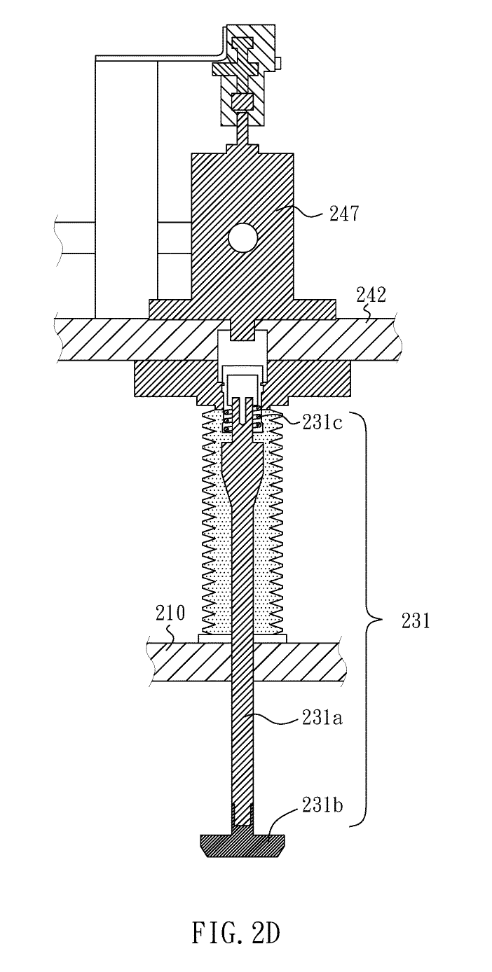

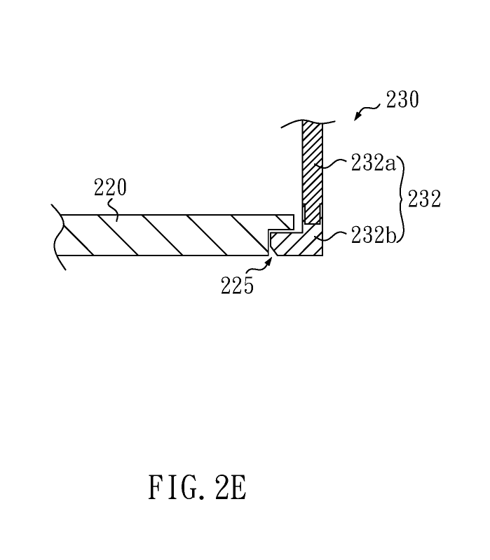

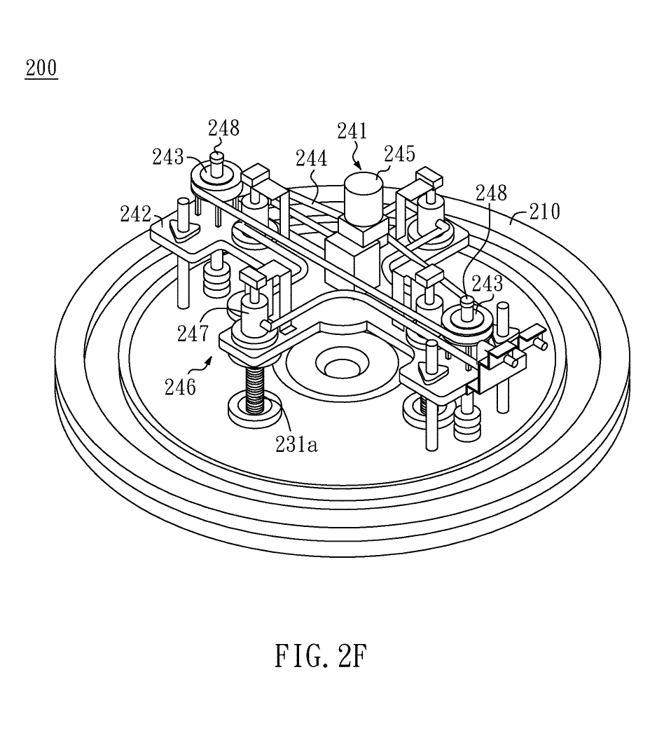

FIG. 2A and FIG. 2B show cross-sectional views of an assembling device 200 adaptable to semiconductor equipment for assembling a ceiling 220 and a chamber lid 210 according to one embodiment of the present invention. The assembling device 200 used for semiconductor equipment may include a chamber lid 210, a ceiling 220, a suspension part 230 and a driving part 240. The ceiling 220 is disposed below the chamber lid 210. The suspension part 230 is inserted through the chamber lid 210 and to be hooked to the ceiling 220. The driving part 240 is disposed above the chamber lid 210 and connected to the suspension part 230, and the driving part 240 is configured to drive the suspension part 230 to join or separate the ceiling 220 and the chamber lid 210. Specifically, the driving part 240 may include an elevating unit 241 and a rotating unit 246. The elevating unit 241 is configured to elevate (i.e., raise or lower) the suspension part 230, and the rotating unit 246 is configured to rotate the suspension part 230.

To be more elaborate, the driving part 240 drives the suspension part 230 to join the ceiling 220 and the chamber lid 210. Specifically, the elevating unit 241 lowers the suspension part 230 and inserts it to the ceiling 220. The rotating unit 246 then rotates the suspension part 230 and hooks it to the ceiling 220. Subsequently, when the elevating unit 241 raises the suspension part 230, the suspension part 230 accordingly raises the ceiling 220 and fastens it to a bottom surface of the chamber lid 210.

In the embodiment, the suspension part 230 may include a plurality of first suspension elements 231 disposed above the ceiling 220. Each first suspension element 231 may include a first support rod 231a and a first hook 231b which is disposed at a bottom end of the first support rod 231a. In one embodiment, the first hook 231b is a T-shaped hook with a top end connected to the bottom end of the first support rod 231a and a bottom end facing toward the ceiling 220.

FIG. 2C shows a partial perspective view of the ceiling 220 and the suspension part 230 of the assembling device 200 of FIGS. 2A-2B. In the embodiment, the ceiling 220 has a plurality of openings 222 disposed corresponding to the first suspension elements 231, respectively. The driving part 240 drives the suspension part 230 to join the ceiling 220 and the chamber lid 210 by the T-shaped first hook 231b and the opening 222 of the ceiling 220. Specifically, the elevating unit 241 lowers the first support rod 231a and inserts it to the opening 222. The rotating unit 246 then rotates the first support rod 231a and hooks the first hook 231b to the ceiling 220. Subsequently, when the elevating unit 241 raises the first support rod 231a, the first hook 231b accordingly raises the ceiling 220 and fastens it to the bottom surface of the chamber lid 210.

Each opening 222 of the ceiling 220 may have a corresponding rotating groove 225. When the rotating unit 246 rotates the first support rod 231a, the first hook 231b accordingly rotates in the rotating groove 225 and finally hooks to a top surface of the rotating groove 225.

When the first hook 231b hooks to the top surface of the rotating groove 225, a thickness of the first hook 231b may be less than or equal to a depth of the rotating groove 225. When assembling the ceiling 220 and the chamber lid 210, the bottom surface of the first hook 231b is at the same level as the bottom surface of the ceiling 220, or is at a higher level than the bottom surface of the ceiling 220. In either case, the first hook 231b does not protrude from the bottom surface of the ceiling 220.

In the embodiment, the ceiling 220 may include a plurality of pads 224 embedded on a top surface of the ceiling 220 and disposed corresponding to the rotating grooves 225. In the embodiment, the pad 224 is disposed surrounding the corresponding opening 222. Accordingly, when the driving part 240 fastens the ceiling 220 toward the bottom surface of the chamber lid 210, a top surface of the pad 224 is in contact with the bottom surface of the chamber lid 210, thereby resulting in a gap between the ceiling 220 and the chamber lid 210.

According to design practice or process requirement, a proper thickness of the pad 224 may be chosen such that the top surface of the pad 224 may be at the same level as the top surface of the ceiling 220, or at a higher level than the top surface of the ceiling 220. The pads 224 and the ceiling 220 may be manufactured integrally or separately. In a case that the top surface of the pad 224 is at a higher level than the top surface of the ceiling 220, a spacing between the top surface of the pad 224 and the top surface of the ceiling 220 may be 0.1-0.3 mm or a proper value according to process conditions or reactant gases. For example, in an arsenic phosphide (AsP) process, a spacing between the top surface of the pad 224 and the top surface of the ceiling 220 may be approximately 0.3 mm such that the spacing between the top surface of the ceiling 220 and the bottom surface of the chamber lid 210 may be maintained at 0.3 mm in the process. In a nitride process, a spacing between the top surface of the pad 224 and the top surface of the ceiling 220 may be approximately 0.1 mm such that the spacing between the top surface of the ceiling 220 and the bottom surface of the chamber lid 210 may be maintained at 0.1 mm in the process.

In one exemplary, but not limiting, embodiment, the assembling device 200 may include four first suspension elements 231, four corresponding openings 222 and four corresponding pads 224. In general, at least two first suspension elements 231, at least two corresponding openings 222 and at least two corresponding pads 224 may be disposed in a balance manner such that the ceiling 220 would not shift laterally or rotate during elevation.

FIG. 2D shows a partial cross-sectional view of the suspension part 230 according to another embodiment of the present invention. Each first suspension element 231 may further include a first buffer component 231c disposed at a top end of the first support rod 231a. When the driving part 240 drives the first support rod 231a and the first hook 231b to raise the ceiling 220 and fastens it to the bottom surface of the chamber lid 210, the first buffer component 231c may substantially reduce the force impacting on the ceiling 220 caused by the first hook 231b, thereby preventing the ceiling 220 from breaking. In one embodiment, the first buffer component 231c may include a spring.

FIG. 2E shows a partial cross-sectional view of the ceiling 220 and a second suspension element 232 of the suspension part 230 according to another embodiment of the present invention. The suspension part 230 may include a plurality of second suspension elements 232. Each second suspension element 232 may include a second support rod 232a and a second hook 232b, which as a whole are L-shaped. The second hook 232b is disposed at a bottom end of the second support rod 232a, and the second hook 232b faces toward the ceiling 220. Accordingly, the driving part 240 drives to lower and rotate the second suspension element 232 of the suspension part 230, and to hook it to an edge of the ceiling 220. Therefore, the ceiling 220 may then be raised and fastened to the bottom surface of the chamber lid 210. The edge of the ceiling 220 may have a rotating groove 225. When the elevating unit 241 lowers the second support rod 232a to the ceiling 220, the rotating unit 246 rotates the second support rod 232a, the second hook 232b accordingly rotates in the rotating groove 225 and finally hooks to a top surface of the rotating groove 225, thereby not affecting the reaction zone. Each second suspension element 232 may further include a second buffer component disposed at a top end of the second support rod 232a. When the ceiling 200 is raised and fastened to the bottom surface of the chamber lid 210, the second buffer component may substantially reduce the force impacting on the ceiling 220 caused by the second hook 232b. The suspension part 230 of the embodiment may selectively include the first suspension element 231 or the second suspension element 232 or their combination.

FIG. 2F shows a perspective view of the driving part 240 of the assembling device 200 of FIGS. 2A-2B. The elevating unit 241 is configured to elevate the first suspension element 231. The elevating unit 241 may include an elevating plate 242, at least two belt pulleys 243, a drive belt 244 and a drive motor 245. The elevating plate 242 is disposed above the chamber lid 210, and is connected to a top end of the first support rod 231a of the first suspension element 231. Specifically, the first support rod 231a is inserted through the chamber lid 210, and is elevated along with the elevating plate 242. The belt pulleys 243 are symmetrically disposed on the elevating plate 242. In one embodiment, a center shaft 248 of the belt pulley 243 is connected to the elevating plate 242, and a bottom end of the center shaft 248 is inserted and screwed to the chamber lid 210. The drive belt 244 is looped over two belt pulleys 243. The drive motor 245 is disposed on the elevating plate 242, and is configured to elevate (i.e., raise or lower) the elevating plate 242 and the first support rod 231a by driving the belt pulleys 243 via the drive belt 244.

The rotating unit 246 may include at least three pneumatic cylinders 247, each of which is correspondingly disposed at a top end of the first support rod 231a, and is configured to rotate the first support rod 231a and the first hook 231b. Although the first suspension element 231 is exemplified in the embodiment as described above, the first suspension element 231 may, however, be substituted or accompanied with the second suspension 232 in other embodiments.

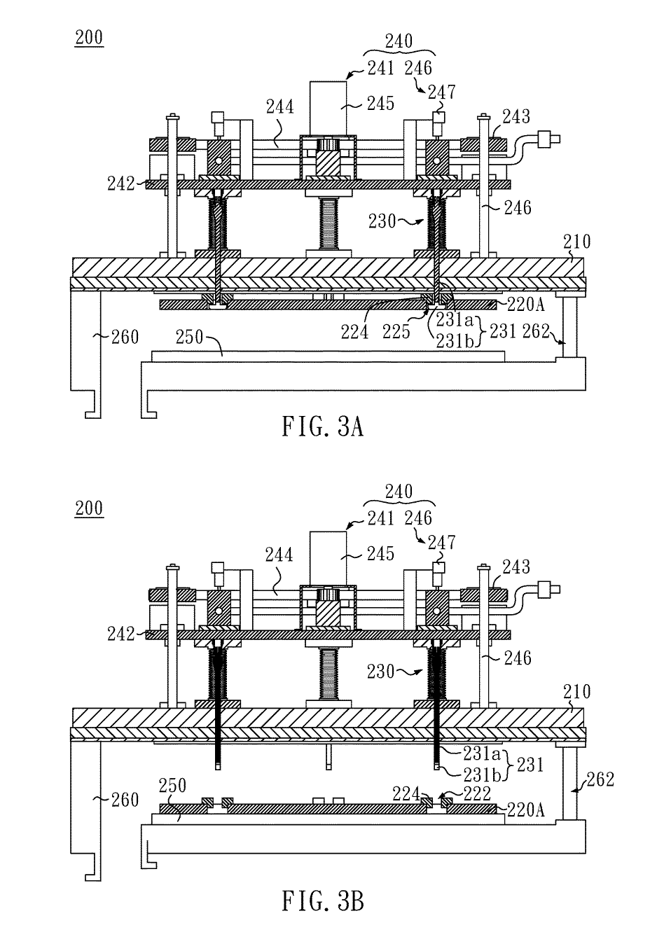

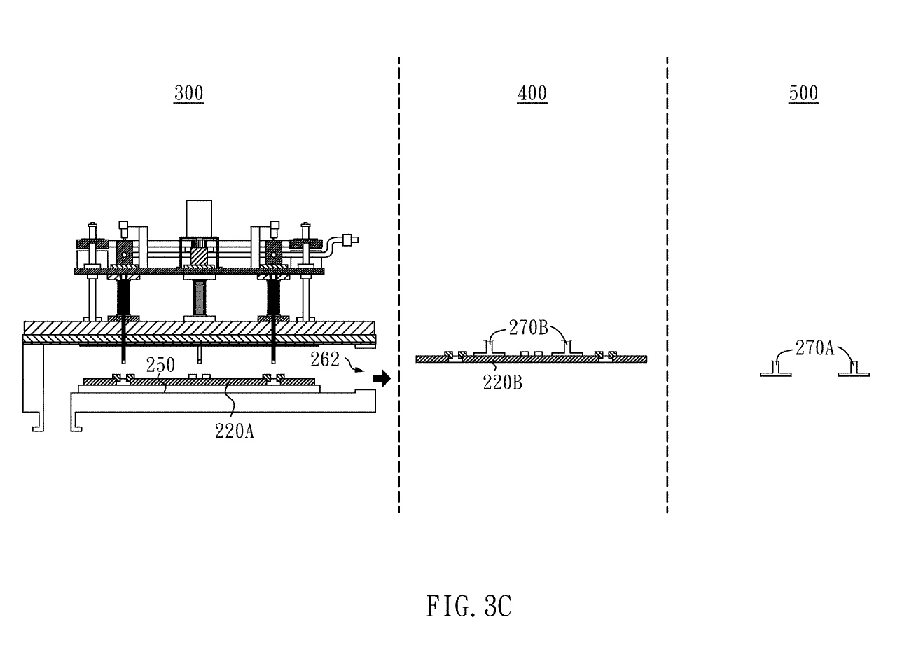

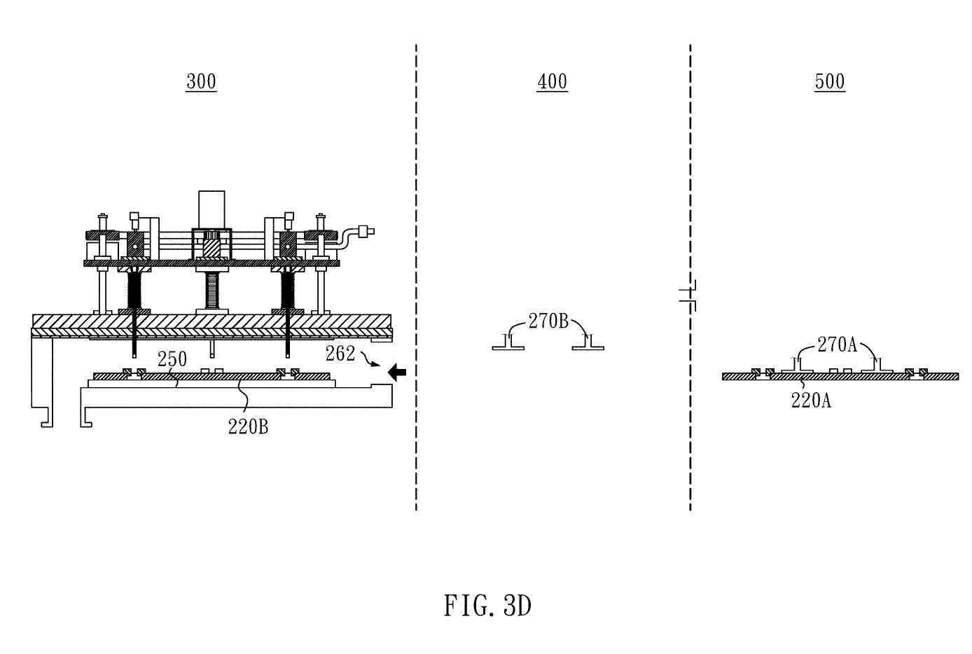

FIG. 3A and FIG. 3B show cross-sectional views of the assembling device 200 adaptable to semiconductor equipment for unloading the ceiling 220 according to another embodiment of the present invention. The driving part 240 drives the suspension part 230 to separate the ceiling 220 from the chamber lid 210. Specifically, the elevating unit 241 drives the belt pulleys 243 via the drive motor 245 and the drive belt 244 to lower the elevating plate 242. The first support rod 231a is thus lowered, and the ceiling 210 is separated from the chamber lid 210 until the ceiling 210 rests on a top surface of a susceptor 250. Subsequently, the pneumatic cylinder 247 of the rotating unit 246 rotates the first support rod 231a, and the first hook 231b then rotates out of the rotating groove 225 corresponding to the opening 222. The drive motor 245 of the elevating unit 241 then raises the first support rod 231a, and the first hook 231b therefore gets away from the opening 222.

FIG. 3C and FIG. 3D show cross-sectional views of the assembling device 200 adaptable to semiconductor equipment for automatically replacing the ceiling according to another embodiment of the present invention. As shown in the figures, the assembling device 200 is disposed in a reaction zone 300, where the chamber lid 210 is disposed at the top of a chamber 260. The assembling device 200 may further include a first robot 270A and a second robot 270B. The chamber 260 may have a gate valve 262. After the process in the chamber 260 finishes, the ceiling 220A is unloaded onto the susceptor 250, and the ceiling 220A is transferred out of the reaction zone 300 through opened gate valve 262 by the first robot 270A and is then disposed in a place zone 500 for cleaning. Subsequently, another ceiling 220B disposed in a standby zone 400 is transferred to the susceptor 250 in the chamber 260 by the second robot 270B. The ceiling 220B is then fastened to the chamber lid 210 by the suspension part 230, followed by closing the gate valve 262, and the chamber 260 is ready for performing another process. Accordingly, the ceiling may be automatically transferred and replaced, thereby effectively reducing manpower and saving time in cooling the chamber 260. Although the first suspension element 231 is exemplified in the embodiment regarding FIGS. 3A-3D, the first suspension element 231 may, however, be substituted or accompanied with the second suspension 232 in other embodiments.

Although specific embodiments have been illustrated and described, it will be appreciated by those skilled in the art that various modifications may be made without departing from the scope of the present invention, which is intended to be limited solely by the appended claims.

What is claimed is:

1. An assembling device used for semiconductor equipment, comprising:
a chamber lid;
a ceiling disposed below the chamber lid;
a suspension part inserted through the chamber lid and to be hooked to the ceiling; and
a driving part disposed above the chamber lid and connected to the suspension part, the driving part being configured to drive the suspension part to join or separate the ceiling and the chamber lid, the driving part comprising:
an elevating unit configured to elevate the suspension part; and
a rotating unit configured to rotate the suspension part.

2. The device of claim 1, wherein when the driving part drives the suspension part to join the ceiling and the chamber lid, the elevating unit lowers the suspension part and inserts the suspension part to the ceiling, the rotating unit then rotates the suspension part and hooks the suspension part to the ceiling, and the elevating unit subsequently raises the suspension part, which accordingly raises the ceiling and fastens the ceiling to a bottom surface of the chamber lid.

3. The device of claim 1, wherein the suspension part comprises a plurality of first suspension elements disposed above the ceiling, each of the first suspension elements comprises:
a first support rod; and
a first hook disposed at a bottom end of the first support rod.

4. The device of claim 3, wherein when the driving part drives the suspension part to join the ceiling and the chamber lid, the elevating unit lowers the first support rod and inserts the first support rod to the ceiling, the rotating unit then rotates the first support rod and hooks the first hook to the ceiling, and the elevating unit subsequently raises the first support rod to accordingly raise the ceiling and fasten the ceiling to a bottom surface of the chamber lid.

5. The device of claim 3, wherein the first hook is T-shaped.

6. The device of claim 3, wherein the ceiling has a plurality of openings disposed corresponding to the first suspension elements, respectively.

7. The device of claim 6, wherein the elevating unit lowers the first support rod and inserts the first support rod to the opening, and the rotating unit then rotates the first support rod and hooks the first hook to the ceiling.

8. The device of claim 6, wherein the opening of the ceiling has a corresponding rotating groove, and when the rotating unit rotates the first support rod, the first hook accordingly rotates in the rotating groove and hooks to a top surface of the rotating groove.

9. The device of claim 8, wherein a thickness of the first hook is less than or equal to a depth of the rotating groove.

10. The device of claim 6, wherein the ceiling comprises a plurality of pads embedded on a top surface of the ceiling and disposed corresponding to the rotating grooves, respectively.

11. The device of claim 10, wherein the pads and the ceiling are manufactured integrally or separately.

12. The device of claim 10, wherein a top surface of the pad is the same as or higher than a top surface of the ceiling, and a spacing between the top surface of the pad and the top surface of the ceiling is 0.1-0.3 mm when the top surface of the pad is higher than the top surface of the ceiling.

13. The device of claim 1, wherein the suspension part comprises a plurality of second suspension elements disposed above an edge of the ceiling, each of the second suspension elements comprises:
a second support rod; and
a second hook disposed at a bottom end of the first support rod.

14. The device of claim 13, wherein the second support rod and the second hook as a whole are L-shaped.

15. The device of claim 13, wherein the second suspension element hooks the edge of the ceiling and raises the ceiling.

16. The device of claim 3, wherein the first suspension element comprises a first buffer component disposed at a top end of the first support rod, and the first buffer component substantially reduces force impacting on the ceiling when raising and fastening the ceiling to a bottom surface of the chamber lid.

17. The device of claim 16, wherein the first buffer component comprises a spring.

18. The device of claim 3, wherein elevating unit comprise:
an elevating plate disposed above the chamber lid and connected to a top end of the first support rod;
at least two belt pulleys disposed on the elevating plate;
a drive belt looped over the belt pulleys; and
a drive motor disposed on the elevating plate, the drive motor being configured to elevate the elevating plate and the first support rod by driving the belt pulleys via the drive belt.

19. The device of claim 18, wherein a center shaft of the belt pulley is connected to the elevating plate, and a bottom end of the center shaft is inserted and screwed to the chamber lid.

20. The device of claim 3, wherein the rotating unit comprises at least three pneumatic cylinders, each of which is correspondingly disposed at a top end of the first support rod, and is configured to rotate the first support rod.

21. The device of claim 1, wherein when the driving part drives the suspension part to separate the ceiling from the chamber lid, the elevating unit lowers the suspension part until the ceiling rests on a susceptor, the rotating unit then rotates the suspension part out of the ceiling, and the elevating unit subsequently raises the suspension part.
